(19) United States
(12) Patent Application Publication
(10) Pub. No.: US 2025/0160072 A1
(43) Pub. Date: May 15, 2025

(54) DISPLAY DEVICE

(71) Applicant: Samsung Display Co., Ltd., Yongin-Si (KR)

(72) Inventors: Tae Young SONG, Yongin-si (KR); Jin Won KIM, Yongin-si (KR); Hye-Jin PAEK, Yongin-si (KR)

(21) Appl. No.: 18/800,131

(22) Filed: Aug. 12, 2024

(30) Foreign Application Priority Data
Nov. 15, 2023 (KR) 10-2023-0158270

(51) Int. Cl. H01L 33/50; H01L 25/075; H01L 25/16

(52) U.S. Cl. CPC H10H 20/8514; H01L 25/0753; H01L 25/167

(57) ABSTRACT

A display device is disclosed that includes a substrate, a transistor disposed on the substrate, a light emitting element electrically connected to the transistor, an encapsulation layer disposed above the light emitting element, a partition disposed on the encapsulation layer and defining a first opening, a second opening, and a third opening, a first color conversion layer disposed in the first opening, a second color conversion layer disposed in the second opening, and a transmissive layer disposed in the third opening, wherein the partition is made of a metal material, and a distance from a center of a portion of the partition to the first color conversion layer is equal to a distance from the center of the portion of the partition to the transmissive layer.

### CROSS-REFERENCE TO RELATED APPLICATION

This application claims priority to and the benefit of Korean Patent Application No. 10-2023-0158270 filed at the Korean Intellectual Property Office on Nov. 15, 2023, the entire contents of which are incorporated herein by reference.

### BACKGROUND

### (a) Field

This disclosure relates to a display device.

### (b) Description of the Related Art

A light emitting element is a device that forms an exciton when a positive hole supplied from an anode and an electron supplied from a cathode combine within a light emitting layer formed between the anode and the cathode, and emits light when this exciton stabilizes. Light-emitting devices have various advantages such as a wide viewing angle, a fast response speed, thinness, and low power consumption, so they are widely applied to various electrical and electronic devices such as televisions, monitors, and mobile phones.

Recently, a display device including a color conversion layer has been proposed to implement a highly efficient display device. The color conversion layer may convert incident light into a different color.

### SUMMARY

Embodiments may provide a high-resolution display device by providing a partition made of a metal material.

A display device according to an embodiment includes a substrate, a transistor disposed on the substrate, a light emitting element electrically connected to the transistor, an encapsulation layer disposed on the light emitting element, a partition disposed on the encapsulation layer and defining a first opening, a second opening and a third opening, a first color conversion layer disposed in the first opening, a second color conversion layer disposed in the second opening, and a transmissive layer disposed in the third opening, wherein the partition is made of a metal material, and a distance from a center of a portion of the partition to the first color conversion layer is equal to a distance from the center of the portion of the partition to the transmissive layer.

The partition may be a single layer.

The transmissive layer, the first color conversion layer, the transmissive layer, and the second color conversion layer may be repeatedly disposed along the first direction.

The upper surface of the transmissive layer may be disposed at a higher level than the upper surface of the first color conversion layer.

The thickness of the partition may be within a range of and including about 0.1 to 5 micrometers.

The display device may include a pattern layer spaced apart from the light emitting element.

The pattern layer may include the same material as the transmissive layer.

The pattern layer may be disposed on the same layer as the first color conversion layer, the second color conversion layer, and the transmissive layer.

The pattern layer may be positioned between the first color conversion layer and the second color conversion layer along a first direction.

A width of the first color conversion layer may be greater than a width of the transmissive layer.

The display device may further include a light blocking layer disposed on the same layer as the partition.

The thickness of the partition may become smaller as it moves toward the substrate.

An upper surface of the partition may include a depression.

The transmissive layer may have a tapered shape.

A display device according to an embodiment includes a substrate, a transistor disposed on the substrate, a light emitting element electrically connected to the transistor, an encapsulation layer disposed on the light-emitting device, on the encapsulation layer, a first opening and a second partition defining an opening and a third opening, a first color conversion layer disposed in the first opening, a second color conversion layer disposed in the second opening, and a transmissive layer disposed in the third opening, wherein the partition is a single layer of metal.

An upper surface of the transmissive layer may be disposed at a higher level than an upper surface of the first color conversion layer.

The thickness of the partition may be within a range of and including about 0.1 to 5 micrometers.

The transmissive layer, the first color conversion layer, the transmissive layer, and the second color conversion layer may be repeatedly disposed along the first direction.

The display device may include a pattern layer spaced apart from the light emitting element.

The pattern layer may be positioned between the first color conversion layer and the second color conversion layer along a first direction.

According to embodiments, a partition made of a metal material is provided, and a color conversion layer formed through an inkjet process may be stably provided.

Additionally, a high-resolution display device may be provided.

### BRIEF DESCRIPTION OF THE DRAWINGS

FIG. 1 is a schematic exploded perspective view of a display device according to an embodiment.

FIG. 2 is a schematic cross-sectional view of a display panel according to an embodiment.

FIG. 3 is a diagram of a portion of a display panel according to an embodiment.

FIG. 4 is a cross-sectional view taken along line A-A′ of FIG. 3.

FIG. 5 is a cross-sectional view taken along line B-B′ of FIG. 3.

FIG. 6A is a detailed cross-sectional view of the embodiment of FIG. 4.

FIG. 6B is a detailed cross-sectional view of another embodiment of FIG. 6A.

FIGS. 7, 8, 9, and 10 are cross-sectional views of a method of manufacturing a display device according to an embodiment.

FIG. 11 is a cross-sectional view of a partial area of a display panel according to another embodiment.

FIGS. 12, 13, 14, 15, and 16 are plan views of partial areas of a display panel according to embodiments.

FIG. 17 is a cross-sectional view of a partial area of a display panel according to an embodiment.

FIGS. 18, 19, and 20 are plan views of partial areas of a display panel according to embodiments.

FIG. 21 and FIG. 22 are cross-sectional views of a partial area of a display panel according to an embodiment.

FIGS. 23, 24, 25, 26, and 27 are cross-sectional views of a portion of a display panel according to embodiments.

### DETAILED DESCRIPTION OF THE EMBODIMENTS

Hereinafter, with reference to the attached drawings, various embodiments of the present disclosure will be described in detail so that those skilled in the art may easily implement the embodiments.

Embodiments may be implemented in many different forms and is not limited to the embodiments described herein.

In order to clearly explain the embodiments, parts that are not relevant to the description are omitted, and identical or similar components are assigned the same reference numerals throughout the specification.

In addition, the size and thickness of each component shown in the drawings are arbitrarily shown for convenience of explanation, so the present disclosure is not necessarily limited to that which is shown.

In the drawing, the thickness may be enlarged to clearly express various layers and areas.

And in the drawings, for convenience of explanation, the thicknesses of some layers and regions may be exaggerated.

Additionally, when a part of a layer, membrane, region, plate, etc. is said to be “above” or “on” another part, this includes not only cases where it is “directly above” another part, but also cases where there is another part in between.

Conversely, when a part is said to be “directly on top” of another part, it means that there is no other part in between.

In addition, being “above” or “on” a reference part means being disposed above or below the reference part, and does not necessarily mean being disposed “above” or “on” it in the direction opposite to gravity.

In addition, throughout the specification, when a part is said to “include” a certain component, this means that it may further include other components rather than excluding other components, unless specifically stated to the contrary.

In addition, throughout the specification, when reference is made to “on a plane,” this means when the target portion is viewed from above, and when reference is made to “in a cross-section,” this means when a cross-section of the target portion is cut vertically and viewed from the side.

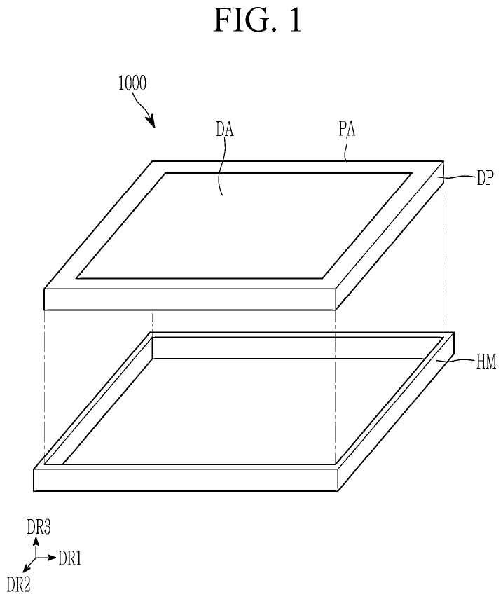

Hereinafter, a display device according to an embodiment will be described with reference to FIG. 1. FIG. 1 is a schematic exploded perspective view of a display device according to an embodiment.

Referring to FIG. 1, a display device 1000 according to an embodiment may include a display panel DP and a housing HM.

One side of the display panel DP on which the image is displayed is parallel to the side defined by the first direction DR1 and the second direction DR2. The third direction DR3 indicates the normal direction of one side on which the image is displayed, that is, the thickness direction of the display panel DP. The front (or upper) and back (or lower) surfaces of each member are separated in the third direction DR3. However, the directions indicated by the first to third directions DR1, DR2, and DR3 are relative concepts and may be converted to other directions.

The display panel DP may be a flat rigid display panel, but is not limited thereto, and may be a flexible display panel. The display panel DP may be made of an organic light emitting display panel. However, the type of display panel DP is not limited to this and may be made of various types of panels. For example, the display panel DP may be made of a liquid crystal display panel, an electrophoretic display panel, an electrowetting display panel, etc.

Additionally, the display panel DP may be made of a next-generation display panel such as a micro light emitting diode display panel, a quantum dot light emitting diode display panel, or a quantum dot organic light emitting diode display panel. Micro LED display panels are made up of light emitting diodes measuring 10 to 100 micrometers to form each pixel. These micro light emitting diode display panels have the following advantages: they use inorganic materials, the backlight may be omitted, the response speed is fast, high brightness may be achieved with low power, and it does not break when bent. Quantum dot light emitting diode display panels are made by attaching a film containing quantum dots or forming them with a material containing quantum dots. Quantum dots are particles made of inorganic materials such as indium and cadmium, and they emit light on their own and have a diameter of several nanometers or less. By controlling the particle size of the quantum dots, light of a desired color may be displayed. The quantum dot organic light emitting diode display panel uses a blue organic light emitting diode as a light source and displays color by attaching a film containing red and green quantum dots on it or depositing a material containing red and green quantum dots.

The display panel DP according to an embodiment may be made of various other display panels.

As shown in FIG. 1, the display panel DP includes a display area DA where an image is displayed, and a non-display area PA adjacent to the display area DA. The non-display area PA is an area where images are not displayed. For example, the display area DA may have a square shape, and the non-display area PA may have a shape surrounding the display area DA. However, the shape of the display area DA and the non-display area PA may be relatively designed without being limited thereto.

The housing HM provides a predetermined internal space. The display panel DP is mounted inside the housing HM. In addition to the display panel DP, various electronic components, such as a power supply unit, a storage device, and an audio input/output module, may be mounted inside the housing HM.

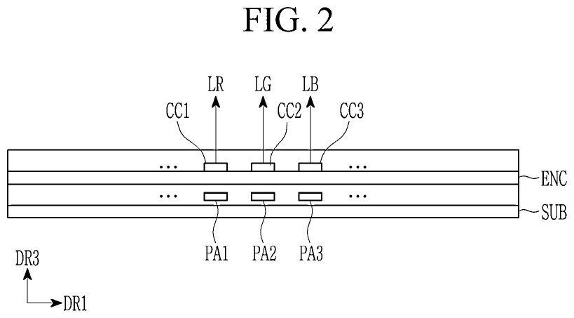

Hereinafter, the display area of the display panel according to an embodiment will be described with reference to FIG. 2. FIG. 2 is a schematic cross-sectional view of a display panel according to an embodiment.

Referring to FIG. 2, a plurality of pixels PA1, PA2, and PA3 may be formed on the substrate SUB corresponding to the display area DA of FIG. 1. Each pixel PA1, PA2, and PA3 may include a plurality of transistors and a light emitting element connected thereto. An encapsulation layer ENC may be disposed on the plurality of pixels PA1, PA2, and PA3. The display area DA may be protected from external air or moisture through the encapsulation layer ENC. The encapsulation layer ENC may be integrally provided to overlap the entire surface of the display area DA, and may be partially disposed on the non-display area PA.

A first color conversion unit CC1, a second color conversion unit CC2, and a transmission unit CC3 may be disposed on the encapsulation layer ENC.

The first color conversion unit CC1 overlaps the first pixel PA1, the second color conversion unit CC2 overlaps the second pixel PA2, and the transmission unit CC3 overlaps the third pixel PA3. Light emitted from the first pixel PA1 may pass through the first color conversion unit CC1 to provide red light LR. Light emitted from the second pixel PA2 may pass through the second color conversion unit CC2 to provide green light LG. Light emitted from the third pixel PA3 may pass through the transmission unit CC3 to provide blue light LB.

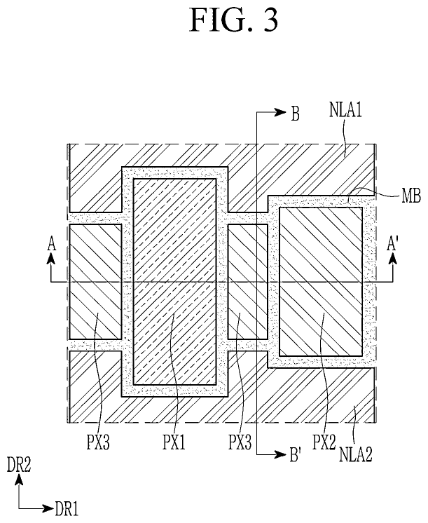

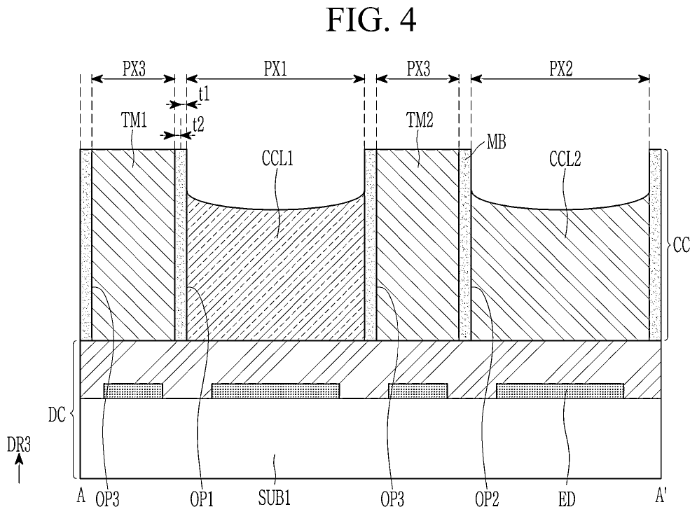

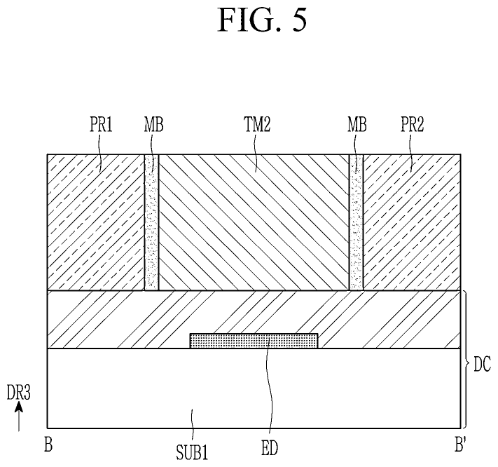

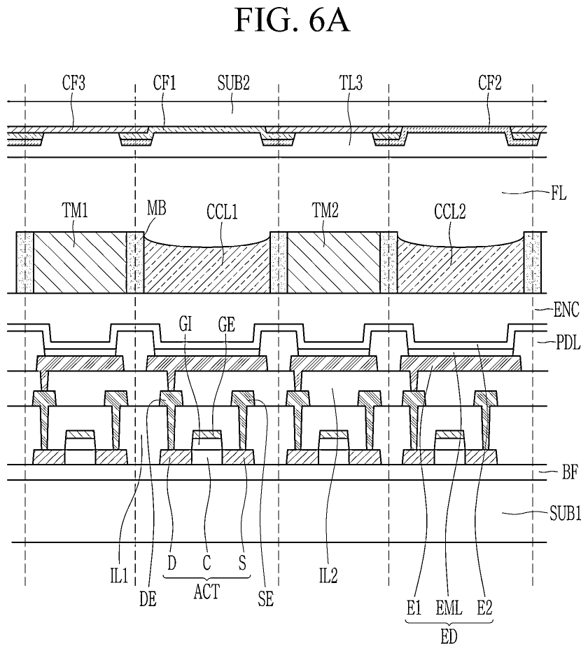

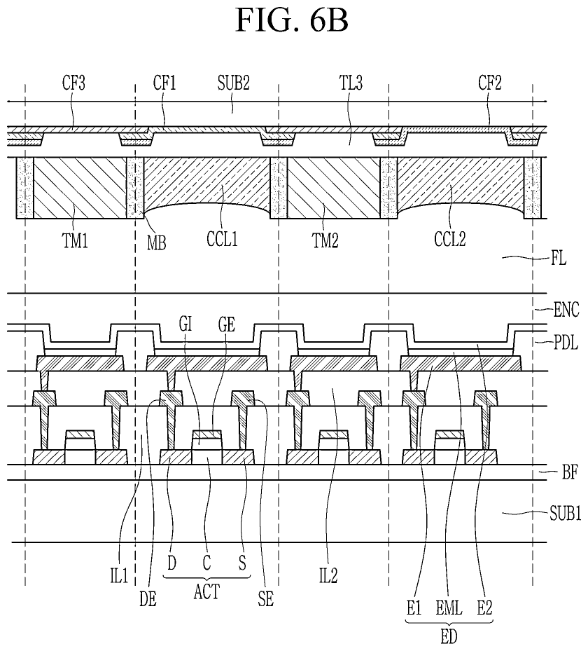

Hereinafter, a display device according to an embodiment will be described with reference to FIGS. 3 to 6. FIG. 3 is a diagram of a portion of a display panel according to an embodiment, FIG. 4 is a cross-sectional view taken along line A-A′ of FIG. 3, FIG. 5 is a cross-sectional view taken along line B-B′ of FIG. 3, FIG. 6A is a specific cross-sectional view of the embodiment of FIG. 4, and FIG. 6B is a specific cross-sectional view of another embodiment.

Referring to FIG. 3, a plurality of pixels are arranged in a display panel according to an embodiment. The plurality of pixels may include a first pixel PX1, a second pixel PX2, and a third pixel PX3. For example, red light may be emitted from the first pixel PX1, green light may be emitted from the second pixel PX2, and blue light may be emitted from the third pixel PX3.

FIG. 3 shows an embodiment in which each of the first pixel PX1, the second pixel PX2, and the third pixel PX3 has a square shape, but is not limited thereto, and the first pixel PX1, the second pixel PX2, and the third pixel PX3 may have various shapes.

In addition, FIG. 3 illustrates an embodiment in which a third pixel PX3, a first pixel PX1, a third pixel PX3, and a second pixel PX2 are arranged along the first direction DR1, but is not limited thereto. The first pixel PX1, the second pixel PX2, and the third pixel PX3 may be arranged in various forms.

Non-light emitting regions NLA1 and NLA2 may be disposed in the second direction DR2 relative to the first pixel PX1, the second pixel PX2, and the third pixel PX3. A partition MB may be disposed between the first pixel PX1, the second pixel PX2, and the third pixel PX3, and a detailed description of the partition MB will be described later.

Referring to FIG. 4, the display panel according to an embodiment may include a color conversion unit CC disposed on a display unit DC. The color conversion unit CC may include a partition MB disposed on the display unit DC. The display unit DC includes a light emitting element ED disposed on the substrate SUB1. The light emitting element ED is described in more detail in the discussion of FIG. 6A and, according to an embodiment, may include a first electrode, a light emitting layer, and a second electrode electrically connected to a transistor.

The partition MB according to an embodiment may be made of a metal material. The metallic partition MB may increase light output efficiency by directly reflecting light emitted toward the side from the color conversion layers CCL1, and CCL2 and transmissive layers TM1 and TM2. The partition MB is located between the first color conversion layer CCL1 and the first transmissive layer TM1, between the first color conversion layer CCL1 and the second transmissive layer TM2, between the second transmissive layer TM2 and the second color conversion layer CCL2, and between the second color conversion layer CCL2 and the first transmissive layer TM1. That is, the partition MB may have a shape surrounding each of the first color conversion layer CCL1, the second color conversion layer CCL2, the first transmissive layer TM1, and the second transmissive layer TM2. The thickness of the partition MB may be within a range and including about 0.1 to 5 micrometers or less, for example, about 1 micrometer or less. The partition MB may be provided with a fairly thin thickness. Therefore, it is possible to provide a high-resolution display device, and at the same time, the reliability of the inkjet process may be improved by securing the width between the first color conversion layer CCL1 and the second color conversion layer CCL2.

The partition MB may define a first opening OP1, a second opening OP2, and a third opening OP3. The sizes of the first opening OP1, the second opening OP2, and the third opening OP3 may be different or the same. The first color conversion layer CCL1 may be disposed within the first opening OP1. The first color conversion layer CCL1 may convert supplied light into red. The first color conversion layer CCL1 may include quantum dots. The second color conversion layer CCL2 may be disposed within the second opening OP2. The second color conversion layer CCL2 may convert supplied light into green light. The second color conversion layer CCL2 may include quantum dots.

The transmissive layers TM1 and TM2 may be disposed within the third opening OP3. The transmissive layers TM1 and TM2 may transmit light supplied from the display unit DC. The transmissive layers TM1 and TM2 may include scatterers. The scatterers may be one or more selected from the group consisting of SiO₂, BaSO₄, Al₂O₃, ZnO, ZrO₂, and TiO₂. The transmissive layers TM1 and TM2 may include a polymer resin and scatterers included in the polymer resin. For example, the transmissive layers TM1 and TM2 may include TiO₂, but are not limited thereto.

The first color conversion layer CCL1 and the second color conversion layer CCL2 may be formed through an inkjet process, and the transmissive layers TM1 and TM2 may be formed through a photolithography process. According to an embodiment, the upper surfaces of the first color conversion layer CCL1 and the second color conversion layer CCL2 may have a shape that is recessed toward the display unit DC. The upper surfaces of the first color conversion layer CCL1 and the second color conversion layer CCL2 may be disposed at a lower level than the upper surfaces of the transmissive layers TM1 and TM2, but are not limited thereto. The widths of the transmissive layers TM1 and TM2 may be smaller than the widths of the first color conversion layer CCL1 and the second color conversion layer CCL2.

The partition MB according to an embodiment may be provided as a single layer of metal. Therefore, the first distance (t1) from the center of the partition MB to the first color conversion layer CCL1 may be equal to the second distance (t2) from the center of the partition MB to the first transmissive layer TM1.

The first color conversion layer CCL1, the second color conversion layer CCL2, and the transmissive layers TM1 and TM2 according to an embodiment may overlap with the light emitting element ED included in the display unit DC.

Referring to FIGS. 3 and 5, non-light emitting regions NLA1 and NLA2 are disposed in the second direction DR2 relative to the first pixel PX1, the second pixel PX2, and the third pixel PX3 according to an embodiment. The non-light emitting regions NLA1 and NLA2 and each pixel PX1, PX2, and PX3 may be separated by a partition MB. Pattern layers PR1 and PR2 formed of the same material as the transmissive layers TM1 and TM2 may be disposed in the non-light emitting regions NLA1 and NLA2. However, since no separate light-emitting elements are disposed in the display unit DC corresponding to the non-light emitting regions NLA1 and NLA2, light is not emitted to the outside of the display device in the non-light emitting regions NLA1 and NLA2.

The pattern layers PR1 and PR2 may be formed of the same material in the same process as the transmissive layers TM1 and TM2. The pattern layers PR1 and PR2 may be disposed on the same layer as the color conversion layers CCL1 and CCL2 and the transmissive layers TM1 and TM2. Since the pattern layers PR1 and PR2 are disposed in the non-light emitting regions NLA1 and NLA2, they may not overlap with the light emitting element ED. The pattern layers PR1 and PR2 may be spaced apart from the light emitting element ED.

In the display panel according to this embodiment, the first color conversion layer CCL1 converts incident light into red light and emits it. Additionally, the second color conversion layer CCL2 converts the incident light into green light and emits it. However, the light incident on the transmissive layers TM1 and TM2 is transmitted without color conversion. The incident light may include blue light. The incident light may be blue light alone or a mixture of blue light and green light. Alternatively, it may include all blue light, green light, and red light.

The quantum dots included in the first color conversion layer CCL1 and the second color conversion layer CCL2 will be described in detail below. In this specification, quantum dots (hereinafter also referred to as semiconductor nanocrystals) include group II-VI compounds, group III-V compounds, group IV-VI compounds, group IV elements or compounds, group I-III-VI compounds, and group II-III compounds. It may include a group VI compound, a group I-II-IV-VI compound, or a combination thereof.

The II-VI group compounds include binary compounds selected from the group consisting of CdSe, CdTe, ZnS, ZnSe, ZnTe, ZnO, HgS, HgSe, HgTe, MgSe, MgS, and mixtures thereof; a tri-element compound selected from; AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. The Group II-VI compound may further include a Group III metal.

The III-V group compounds include binary compounds selected from the group consisting of GaN, GaP, GaAs, GaSb, AlN, AIP, AlAs, AlSb, InN, InP, InAs, InSb, and mixtures thereof; A ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and mixtures thereof; and a quaternary compound selected from the group consisting of GaAINP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof. The group III-V compound may further include a group II metal (e.g., InZnP).

The IV-VI group compounds include binary compounds selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary element compound selected from the group consisting of SnPbSSe, SnPbSeTe, SnPbSTe, and mixtures thereof.

The Group IV element or compound is a monoelement compound selected from the group consisting of Si, Ge, and combinations thereof; and a binary compound selected from the group consisting of SiC, SiGe, and combinations thereof, but is not limited thereto.

Examples of the Group I-III-VI compounds include, but are not limited to, CuInSe₂, CuInS₂, CuInGaSe, and CuInGaS.

Examples of the Group I-II-IV-VI compounds include, but are not limited to, CuZnSnSe and CuZnSnS.

The group II-III-VI compounds include ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, and may be selected from the group consisting of HgInTe, MgGaS, MgAlS, MgInS, MgGaSe, MgAlSe, MgInSe, and combinations thereof, but are not limited thereto.

The group I-II and group IV-VI compound may be selected from CuZnSnSe and CuZnSnS, but is not limited thereto.

In an embodiment, the quantum dots may not include cadmium.

Quantum dots may include semiconductor nanocrystals based on group III-V compounds including indium and phosphorus. The group III-V compound may further include zinc.

Quantum dots may include semiconductor nanocrystals based on group II-VI compounds including chalcogen elements (e.g., sulfur, selenium, tellurium, or combinations thereof) and zinc.

In the quantum dots, the above-mentioned binary compound, ternary compound, or quaternary compound may exist in particles at a uniform concentration, or may exist in the same particle with a concentration distribution partially divided into different states.

Additionally, one quantum dot may have a core/shell structure surrounding other quantum dots. The interface between the core and the shell may have a concentration gradient in which the concentration of elements present in the shell decreases toward the center. In some embodiments, quantum dots may have a core-shell structure including a core containing the above-described nanocrystals and a shell surrounding the core. The shell of the quantum dot may serve as a passivation layer to maintain semiconductor properties by preventing chemical denaturation of the core or as a charging layer to impart electrophoretic properties to the quantum dot. The shell may be single- or multi-layered. The interface between the core and the shell may have a concentration gradient in which the concentration of elements present in the shell decreases toward the center.

Examples of the shell of the quantum dot include metal or non-metal oxides, semiconductor compounds, or combinations thereof. For example, the oxide of the metal or non-metal is a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or MgAl₂O₄, CoFe₂O₄, NiFe₂O₄, CoMn₂O₄, etc., but the present disclosure is not limited thereto. In addition, the semiconductor compounds include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. However, the present disclosure is not limited thereto.

The interface between the core and the shell may have a concentration gradient in which the concentration of elements present in the shell decreases toward the center. Additionally, the semiconductor nanocrystal may have a structure including a single semiconductor nanocrystal core and a multi-layered shell surrounding it. In an embodiment, the multilayer shell may have two or more layers, such as 2, 3, 4, 5, or more layers. The two adjacent layers of the shell may have a single composition or different compositions. In a multilayer shell, each layer may have a composition that changes along the radius.

Quantum dots may have a full width of half maximum (FWHM) of the emission wavelength spectrum of about 45 nm or less, preferably about 40 nm or less, more preferably about 30 nm or less, and within this range, color purity or color reproducibility may be improved. Additionally, since the light emitted through these quantum dots is emitted in all directions, the optical viewing angle may be improved.

The quantum dots may have different energy band gaps between the shell material and the core material. For example, the energy band gap of the shell material may be larger than that of the core material. In other embodiments, the energy band gap of the shell material may be smaller than that of the core material.

The quantum dots may have a multi-layered shell. In a multilayer shell, the energy band gap of the outer layer may be larger than that of the inner layer (i.e., the layer closer to the core). In a multilayer shell, the energy band gap of the outer layer may be smaller than that of the inner layer.

Quantum dots may control absorption/emission wavelengths by adjusting their composition and size. The maximum emission peak wavelength of the quantum dot may range from ultraviolet to infrared wavelengths or longer.

Quantum dots may have quantum efficiency of at least about 10%, such as at least about 30%, at least about 50%, at least about 60%, at least about 70%, at least about 90%, or 100%.

The quantum dots may have a relatively narrow spectrum. The quantum dots may have a full width at half maximum of the emission wavelength spectrum of, for example, about 50 nm or less, such as about 45 nm or less, about 40 nm or less, or about 30 nm or less.

The quantum dots may have a particle size of about 1 nm or more and about 100 nm or less. The size of a particle refers to the diameter of the particle or the diameter converted by assuming a spherical shape from a two-dimensional image obtained by transmission electron microscopy analysis. The quantum dots may have a size of about 1 nm to about 20 nm, such as at least 2 nm, at least 3 nm, or at least 4 nm, and at most 50 nm, at most 40 nm, at most 30 nm, at most 20 nm, or at most 15 nm, or at least 10 nm or less.

The shape of the quantum dot is not particularly limited. For example, the shape of the quantum dot may include, but is not limited to, a sphere, a polyhedron, a pyramid, a multipod, a square, a cuboid, a nanotube, a nanorod, a nanowire, a nanosheet, or a combination thereof.

Quantum dots are commercially available or may be appropriately synthesized. The particle size of quantum dots may be controlled relatively freely during colloid synthesis, and the particle size may also be adjusted uniformly.

Quantum dots may include organic ligands (e.g., having hydrophobic or hydrophilic moieties). The organic ligand residue may be bound to the surface of the quantum dot. The organic ligand includes RCOOH, RNH₂, R₂NH, R₃N, RSH, R₃PO, R₃P, ROH, RCOOR, RPO(OH)₂, RHPOOH, R₂POOH, or a combination thereof, where each R is independently a substituted or unsubstituted C3 to C40 alkyl (e.g., C5 or more and C24 or less), a substituted or unsubstituted alkenyl, a substituted or unsubstituted C3 to C40 aliphatic hydrocarbon group, a substituted or unsubstituted C6 to C40 aryl group, a substituted or unsubstituted C6 to C40 (e.g., C6 or more and C20 or less) aromatic hydrocarbon group, or a combination thereof.

Examples of the organic ligand include thiol compounds such as methane thiol, ethane thiol, propane thiol, butane thiol, pentane thiol, hexane thiol, octane thiol, dodecane thiol, hexadecane thiol, octadecane thiol, and benzyl thiol; methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, and dipropyl amine, amines such as tributylamine, trioctylamine, etc.; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octyl phosphine, dioctyl phosphine, tributyl phosphine, trioctyl phosphine, etc.; phosphines such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, and trioctyl phosphine oxide; diphenyl phosphine or triphenyl phosphine compounds or their oxide compounds; C5 to C20 alkyl phosphonic acids such as hexylphosphinic acid, octylphosphinic acid, dodecanephosphinic acid, tetradecanephosphinic acid, hexadecanephosphinic acid, and octadecanephosphinic acid; but are not limited to these.

Quantum dots may include hydrophobic organic ligands alone or in a mixture of one or more types. The hydrophobic organic ligand may not contain a photopolymerizable residue (e.g., an acrylate group, a methacrylate group, etc.).

Although not shown in the drawings, a separate passivation layer may be disposed between the first color conversion layer and the partition, between the second color conversion layer and the partition, and between the transmissive layer and the partition. The passivation layer may be an inorganic or organic material. The passivation layer may serve to protect the partition made of metal.

Hereinafter, a cross-section of the display panel including the color conversion unit CC and the display unit DC described above will be described in more detail with reference to FIGS. 6A and 6B. Description of at least some of the above-mentioned components are omitted.

First, referring to FIG. 6A, the display unit according to an embodiment includes a first substrate SUB1. The first substrate SUB1 may include a flexible material such as plastic that may bend, fold, or roll. The buffer layer BF may be disposed on the first substrate SUB1. The buffer layer BF may include silicon nitride SiNₓ, silicon dioxide SiO₂, or silicon oxynitride. The buffer layer BF is disposed between the first substrate SUB1 and the semiconductor layer ACT, and improves the properties of polycrystalline silicon by blocking impurities from the first substrate SUB1 during the crystallization process to form polycrystalline silicon, and by flattening the first substrate SUB1, the stress of the semiconductor layer ACT formed on the buffer layer BF may be alleviated.

A semiconductor layer ACT is disposed on the buffer layer BF. The semiconductor layer ACT may be made of polycrystalline silicon or an oxide semiconductor. The semiconductor layer ACT includes a channel region C, a source region S, and a drain region D. The source region S and the drain region D are respectively arranged on both sides of the channel region C. The channel region C is an intrinsic semiconductor that is not doped with impurities, and the source region S and the drain region D are impurity semiconductors that are doped with conductive impurities.

The semiconductor layer ACT may be made of an oxide semiconductor. In this case, a passivation layer (not shown) may be added to protect the oxide semiconductor material, which is vulnerable to external environments such as a high temperature.

A gate insulating layer GI is disposed on the semiconductor layer ACT. The gate insulating layer GI may be a single layer or a multilayer containing at least one of a silicon nitride (SiNₓ), silicon dioxide (SiO₂), and silicon oxynitride. A gate electrode GE is disposed on the gate insulating layer GI, and the gate electrode GE includes any one of copper (Cu), a copper alloy, aluminum (Al), an aluminum alloy, molybdenum (Mo), and a molybdenum alloy, and it may be a multilayer in which metal films are stacked.

An interlayer insulating layer IL1 is disposed on the gate electrode GE and the gate insulating layer GI. The interlayer insulating layer IL1 may include a silicon nitride (SiNₓ), silicon dioxide (SiO₂), or silicon oxynitride.

Openings exposing the source region S and the drain region D are disposed in the interlayer insulating layer IL1. A source electrode SE and a drain electrode DE are disposed on the interlayer insulating layer IL1. The source electrode SE and the drain electrode DE are respectively connected to the source region S and the drain region D of the semiconductor layer ACT through openings formed in the interlayer insulating layer IL1.

A passivation layer IL2 is disposed on the interlayer insulating layer IL1, the source electrode SE, and the drain electrode DE. The passivation layer IL2 covers and flattens the interlayer insulating layer IL1, the source electrode SE, and the drain electrode DE, so that the first electrode E1 may be formed on the passivation layer IL2 without steps. This passivation layer IL2 may be made of an organic material such as a polyacrylate resin or a polyimide resin, or a laminated film of an organic material and an inorganic material.

The first electrode E1 is disposed on the passivation layer IL2. The first electrode E1 is connected to the drain electrode DE through an opening in the passivation layer IL2.

A driving transistor including the gate electrode GE, the semiconductor layer ACT, the source electrode SE, and the drain electrode DE is electrically connected to the first electrode E1 to supply a driving current to the light emitting element ED.

In addition to the driving transistor shown in FIG. 6A, the display device according to the present embodiment includes a switching transistor (not shown) connected to the data line and transmitting a data voltage in response to a scan signal, and a switching transistor (not shown) connected to the driving transistor and driven in response to the scan signal, and it may further include a compensation transistor (not shown) that compensates the threshold voltage of the transistor.

A pixel defining layer PDL is positioned on the passivation layer IL2 and the first electrode E1, and the pixel defining layer PDL may have a pixel opening that overlaps the first electrode E1 and defines a light emitting area. The pixel defining layer PDL may contain an organic material such as a polyacrylate resin or a polyimide resin, or a silica-based inorganic material. The pixel opening may have a planar shape substantially similar to that of the first electrode E1, and may have a diamond or octagonal shape similar to a diamond in a plan, but is not limited thereto and may have any shape such as a square or a polygon.

The light emitting layer EML is disposed on the first electrode E1 overlapping the pixel opening. The light-emitting layer EML may be made of a low-molecular organic material or a high-molecular organic material such as PEDOT poly(3,4-ethylenedioxythiophene). In addition, the light emitting layer EML may include a hole injection layer HIL, a hole transporting layer HTL, an electron transporting layer ETL, and an electron injection layer EIL, and it may be a multilayer containing one or more layers. The emitting layer EML may be disposed mostly within the pixel opening, and may also be disposed on the side or on the pixel defining layer PDL.

The second electrode E2 is disposed on the light emitting layer EML. The second electrode E2 may be disposed across a plurality of pixels and may receive a common voltage through a common voltage transmitter (not shown) in the non-display area.

The first electrode E1, the light emitting layer EML, and the second electrode E2 may form a light emitting element ED. Here, the first electrode E1 may be an anode, which is a hole injection electrode, and the second electrode E2 may be a cathode, which is an electron injection electrode. However, the embodiment is not necessarily limited to this, and the first electrode E1 may be a cathode and the second electrode E2 may be an anode depending on the driving method of the organic light emitting display device. Holes and electrons are injected into the light emitting layer EML from the first electrode E1 and the second electrode E2, respectively, and light emission occurs when the exciton combined with the injected holes and electrons falls from an excited state to a ground state.

An encapsulation layer ENC is positioned on the second electrode E2. The encapsulation layer ENC may seal the display layer by covering not only the top surface but also the side surfaces of the display layer including the light emitting element ED. Since the light emitting element is vulnerable to moisture and oxygen, the encapsulation layer ENC seals the display layer and blocks the inflow of external moisture and oxygen. The encapsulation layer ENC may include a plurality of layers, and may be formed as a composite film including both an inorganic layer and an organic layer, and may be a triple layer in which a first inorganic layer, an organic layer, and a second inorganic layer are formed sequentially.

The color conversion unit described above is disposed on the encapsulation layer ENC. The color conversion unit includes a partition MB disposed on the encapsulation layer ENC. Additionally, a first color conversion layer CCL1, a second color conversion layer CCL2, a first transmissive layer TM1, and a second transmissive layer TM2 may be disposed within the opening of the partition MB.

The color conversion unit includes a second substrate SUB2 that overlaps the first substrate SUB1. The second substrate SUB2 may include a flexible material such as a plastic that may bend, fold, or roll easily.

A filling layer FL may be disposed on the partition MB, the first color conversion layer CCL1, the second color conversion layer CCL2, and the transmissive layers TM1 and TM2. The filling layer FL may combine components disposed on the first substrate SUB1 and components disposed on the second substrate SUB2. One display panel may be formed through the filling layer FL.

A color filter unit includes a first color filter CF1, a second color filter CF2, and a third color filter CF3 disposed between the second substrate SUB2 and the display unit. The first color filter CF1 may overlap the first color conversion layer CCL1. The first color filter CF1 may transmit red light that has passed through the first color conversion layer CCL1 and absorb light of the remaining wavelengths, thereby increasing the purity of red light emitted to the outside of the display device. The second color filter CF2 may overlap the second color conversion layer CCL2. The second color filter CF2 may transmit green light that has passed through the second color conversion layer CCL2 and absorb light of the remaining wavelengths, thereby increasing the purity of green light emitted to the outside of the display device. The third color filter CF3 may overlap the first transmissive layer TM1 and the second transmissive layer TM2. The third color filter CF3 transmits the blue light that has passed through the first transmissive layer TM1 and the second transmissive layer TM2 and absorbs light of the remaining wavelengths, thereby increasing the purity of the blue light emitted to the outside of the display device.

At least two of the third color filter CF3, the second color filter CF2, and the first color filter CF1 may overlap each other to serve as a light blocking layer. For example, the first and third color filters CF1 and CF3 may overlap. For example, the second and third color filters CF2 and CF3 may overlap. A portion where at least two color filters of CF1, CF2, and CF3 overlap may overlap with the partition MB.

According to an embodiment, the portion where the pixel defining layer PDL, the partition MB, and at least two of color filters CF1, CF2, and CF3 overlap may be disposed between adjacent light emitting layers EML overlap is the first substrate SUB1, and may be overlapped along the thickness direction. In particular, the center of the pixel defining layer PDL disposed between the light emitting layer EML, the center of the partition MB, and the center of the area where at least two of color filters CF1, CF2, and CF3 substantially overlap along an imaginary line extending along the thickness direction of the substrate SUB1. In addition, although not shown in FIG. 6A, the overlapping portion of at least two of color filters CF1, CF2, and CF3 may also overlap with the pattern layers PR1 and PR2 disposed in the non-light emitting regions NLA1 and NLA2.

Additionally, according to an embodiment, a passivation layer TL3 may be positioned between the color filters CF1, CF2, and CF3 and the filling layer FL. The passivation layer TL3 may include an organic insulating material or an inorganic insulating material.

Referring to FIG. 6B, the display device according to an embodiment may have a stacked structure of the first substrate SUB1 to the encapsulation layer ENC, the same as that of FIG. 6A.

Additionally, the display device according to an embodiment includes a second substrate SUB2 that overlaps the first substrate SUB1. The second substrate SUB2 may include a flexible material such as plastic that may bend, fold, or roll easily. A first color filter CF1, a second color filter CF2, and a third color filter CF3 may be disposed on a side of the second substrate SUB2 facing the first substrate SUB1. The first color filter CF1 may overlap the first color conversion layer CCL1. The second color filter CF2 may overlap the second color conversion layer CCL2. The third color filter CF3 may overlap the first transmissive layer TM1 and the second transmissive layer TM2. At least two of the third color filter CF3, the second color filter CF2, and the first color filter CF1 may overlap each other to serve as a light blocking layer. A portion where at least of two color filters CF1, CF2, and CF3 overlap may overlap with the partition MB.

A passivation layer TL3 may be disposed on the first color filter CF1, the second color filter CF2, and the third color filter CF3. The above-described partition MB, first color conversion layer CCL1, second color conversion layer CCL2, and transmissive layers TM1 and TM2 may be disposed on the passivation layer TL3.

A filling layer FL may be disposed on the partition MB, the first color conversion layer CCL1, the second color conversion layer CCL2, and the transmissive layers TM1 and TM2. The filling layer FL may combine components disposed on the first substrate SUB1 and components disposed on the second substrate SUB2. One display panel may be formed through the filling layer FL.

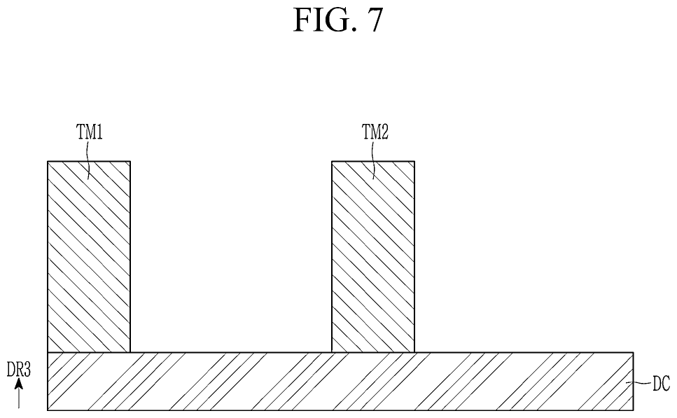

Hereinafter, a method of manufacturing a display device according to an embodiment will be described with reference to FIGS. 7 to 10. FIGS. 7, 8, 9, and 10 are cross-sectional views of a method of manufacturing a display device according to an embodiment. Descriptions of at least some of the components that are the same as those described above are omitted.

Referring to FIG. 7, a first transmissive layer TM1 and a second transmissive layer TM2 are formed on the display unit DC manufactured according to an embodiment using a photosensitive resin composition. In the process of forming the first transmissive layer TM1 and the second transmissive layer TM2, the first pattern layer PR1 and the second pattern layer PR2 disposed in the non-light emitting regions NLA1 and NLA2 may also be formed.

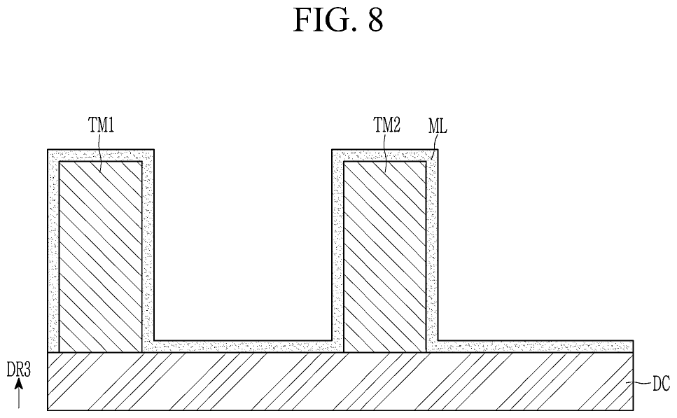

Then, the metal layer ML is deposited to overlap the entire surface of the display unit DC, as shown in FIG. 8.

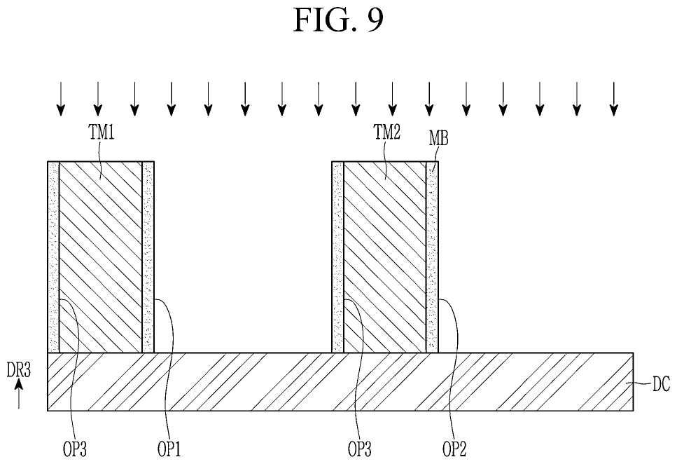

Afterwards, as shown in FIG. 9, an anisotropic etching process of the metal layer ML is performed to form a partition MB covering the side surfaces of the first and second transmissive layers TM1 and TM2.

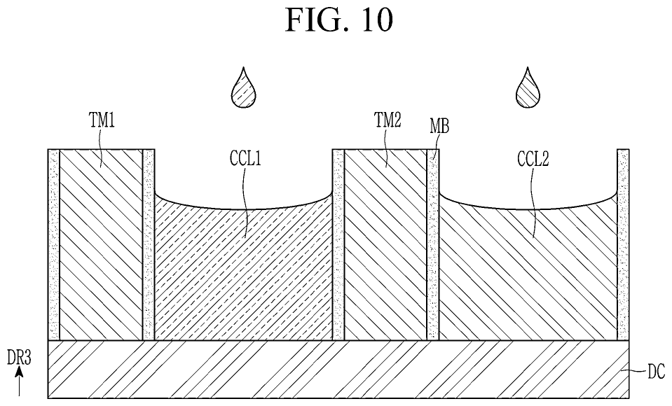

Next, as shown in FIG. 10, the first color conversion layer CCL1 and the second color conversion layer CCL2 are formed through an inkjet process. According to an embodiment, a partition MB and a transmissive layer TM1, TM2 are formed between the first color conversion layer CCL1 and the second color conversion layer CCL2 manufactured through an inkjet process, thereby ensuring a sufficient process margin. Therefore, it may be possible to provide a first color conversion layer CCL1 and a second color conversion layer CCL2 that are stably formed without color mixing.

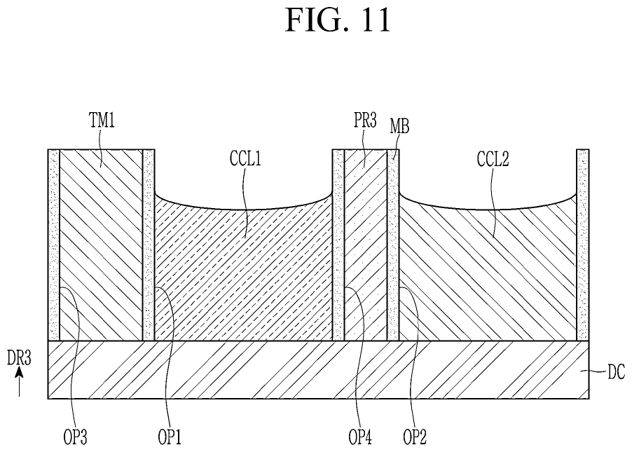

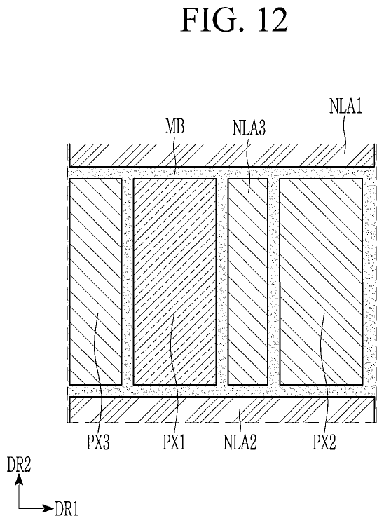

Hereinafter, a display device according to embodiments will be described with reference to FIGS. 11 to 16. FIG. 11 is a cross-sectional view of a partial area of a display panel according to an embodiment, and FIGS. 12, 13, 14, 15, and 16 are plan views of a partial area of the display panel according to embodiments.

Descriptions of at least some of the components that are the same as those described above are omitted.

Referring to FIG. 11, the partition MB according to an embodiment may define a first opening OP1, a second opening OP2, a third opening OP3, and a fourth opening OP4. The first color conversion layer CCL1 may be disposed in the first opening OP1, and the second color conversion layer CCL2 may be disposed in the second opening OP2. The first transmissive layer TM1 may be disposed in the third opening OP3, and the third pattern layer PR3 may be disposed in the fourth opening OP4. The first transmissive layer TM1 and the third pattern layer PR3 may be formed in the same process and may include the same material. However, transistors and light-emitting elements may be disposed at the bottom of the first transmissive layer TM1, and transistors and light-emitting elements may not be disposed at the bottom of the third pattern layer PR3. Blue light may be emitted from the first transmissive layer TM1, and no light is emitted from the third pattern layer PR3.

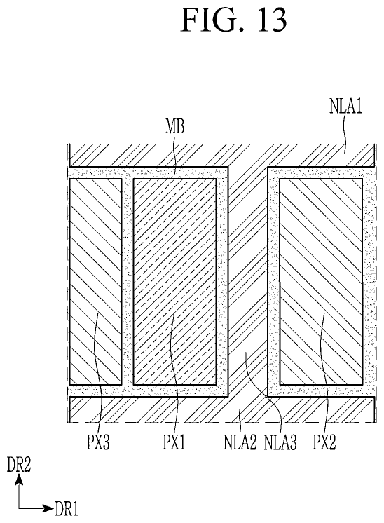

Referring to FIG. 12, the third pixel PX3, the first pixel PX1, the non-light emitting region NLA3, and the second pixel PX2 may be arranged along the first direction DR1. That is, referring to FIG. 11, the transmissive layer TM1, the first color conversion layer CCL1, the pattern layer PR3, and the second color conversion layer CCL2 may be arranged in that order. The third pixel PX3, the first pixel PX1, the non-light emitting region NLA3, and the second pixel PX2 may be separated by a partition MB. In the second direction DR2, a first non-light emitting region NLA1 may be disposed at the upper part of the third pixel PX3, the first pixel PX1, the non-light emitting region NLA3, and the second pixel PX2, and a second non-light emitting region NLA2 may be disposed at the bottom of the third pixel PX3, the first pixel PX1, the non-light emitting region NLA3, and the second pixel PX2. However, it is not limited to these embodiments, and the partition disposed between the first non-light emitting region NLA1, the second non-light emitting region NLA2, and the third non-light emitting region NLA3 may be removed as shown in FIG. 13.

According to the embodiment of FIG. 13, the partition MB may be provided to surround the first pixel PX1, the second pixel PX2, and the third pixel PX3.

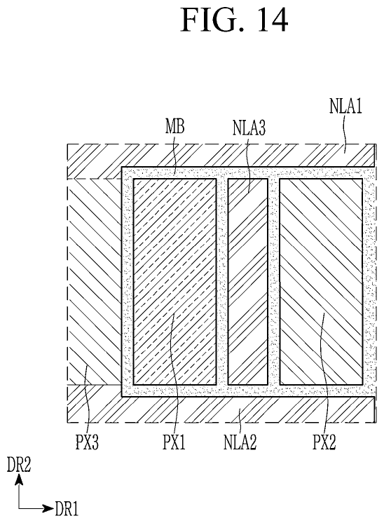

Alternatively, as shown in FIG. 14, the partition disposed between the first non-light emitting region NLA1, the second non-light emitting region NLA2, and the third pixel PX3 may be removed. According to the embodiment of FIG. 14, the partition MB may be provided to surround the first pixel PX1, the second pixel PX2, and the third non-light emitting region NLA3.

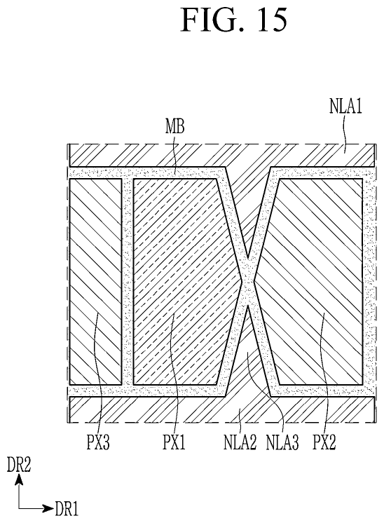

Referring to FIG. 15, the partition MB may have a shape surrounding the first pixel PX1, the second pixel PX2, and the third pixel PX3. Each of the first pixel PX1 and the second pixel PX2 may have a polygonal shape, and the first pixel PX1 and the second pixel PX2 may have a symmetrical shape.

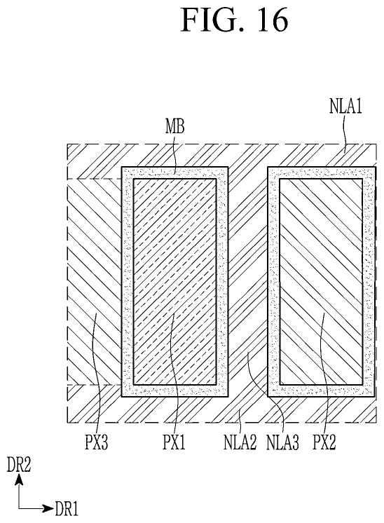

Alternatively, as shown in FIG. 16, the partition MB may have a shape surrounding the first pixel PX1 and the second pixel PX2. The partition MB may not be disposed between the first non-light emitting region NLA1, the second non-light emitting region NLA2, the third non-light emitting region NLA3, and the third pixel PX3.

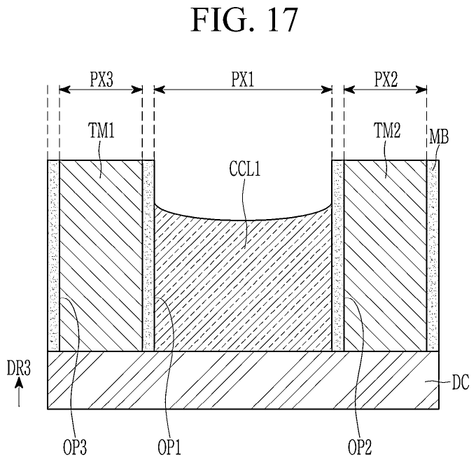

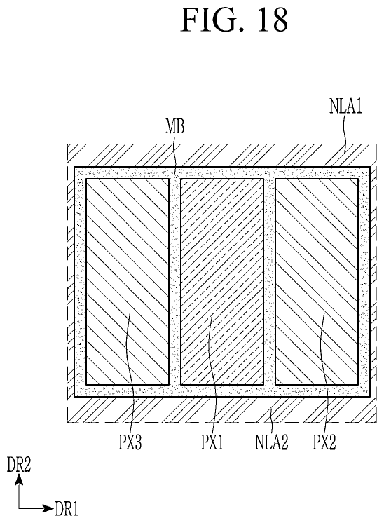

Hereinafter, a display device according to embodiments will be described with reference to FIGS. 17 to 20. FIG. 17 is a cross-sectional view of a partial area of the display panel according to an embodiment, and FIGS. 18, 19, and 20 are plan views of a partial area of the display panel according to embodiments.

Referring to FIG. 17, a first transmissive layer TM1, a first color conversion layer CCL1, and a second transmissive layer TM2 may be disposed on the display unit DC. A partition MB may be disposed between the first transmissive layer TM1 and the first color conversion layer CCL1, between the first color conversion layer CCL1 and the second transmissive layer TM2, and between the first transmissive layer TM1 and the second transmissive layer TM2. Red light is emitted from the first pixel PX1 overlapping the first color conversion layer CCL1, blue light is emitted from the third pixel PX3 overlapping the first transmissive layer TM1, and green light may be emitted from the second pixel PX2 overlapping the second transmissive layer TM2.

As shown in FIG. 18, the area where the first transmissive layer TM1 is disposed is the third pixel PX3, the area where the first color conversion layer CCL1 is disposed is the first pixel PX1, the area where the first color conversion layer CCL1 is disposed is the first pixel PX1, and the area where the transmissive layer TM2 is disposed may be the second pixel PX2. The third pixel PX3, the first pixel PX1, and the second pixel PX2 may be repeatedly arranged along the first direction DR1. The partition MB may have a shape surrounding the first pixel PX1, the second pixel PX2, and the third pixel PX3.

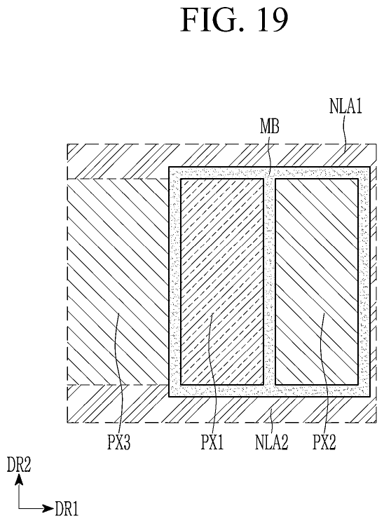

Alternatively, as shown in FIG. 19, the partition MB may have a shape removed between the first non-light emitting region NLA1, the second non-light emitting region NLA2, and the third pixel PX3.

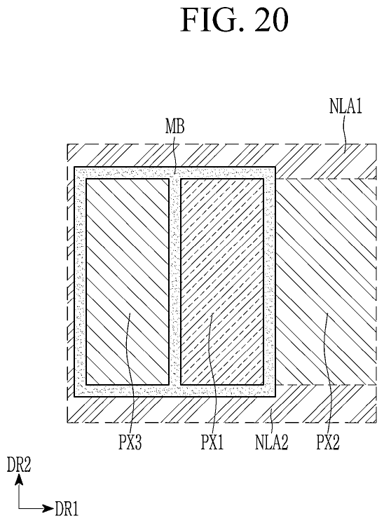

Alternatively, as shown in FIG. 20, the partition MB may have a shape removed between the first non-light emitting region NLA1, the second non-light emitting region NLA2, and the second pixel PX2.

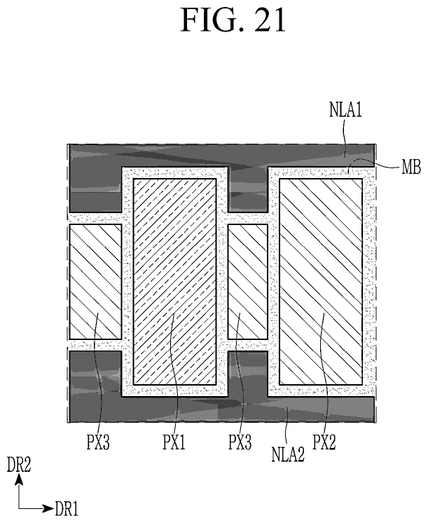

Hereinafter, a display device according to embodiments will be described with reference to FIGS. 21 to 27.

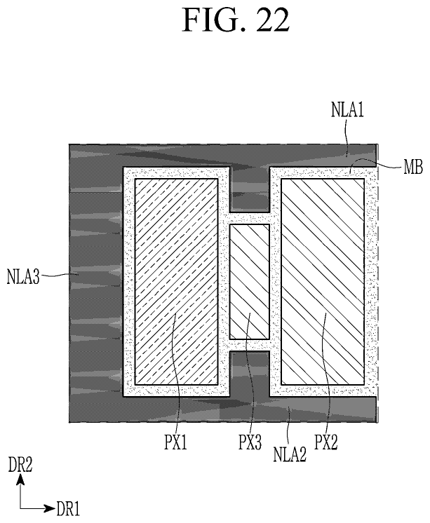

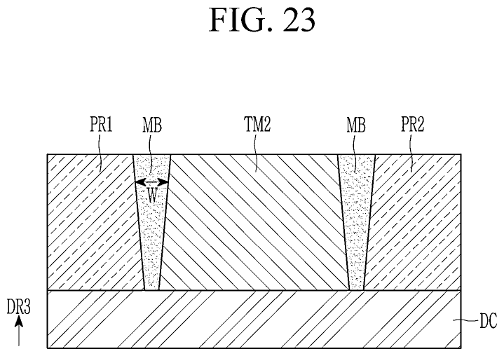

FIGS. 21 and 22 are plan views of a part of the display panel according to embodiments, and FIGS. 23, 24, 25, 26, and 27 are each cross-sectional views of a part of the display panel according to embodiments. Descriptions of at least some of the components that are the same as those described above are omitted.

Referring to FIG. 21, each of the first non-light emitting region NLA1 and the second non-light emitting region NLA2 may further include a light blocking layer disposed on the same layer as the pattern layer of the third pixel PX3.

Alternatively, as shown in FIG. 22, the third non-light emitting region NLA3 may further include a light blocking layer disposed on the same layer as the pattern layer of the third pixel PX3.

Referring to FIG. 23, each of the transmissive layer TM2 and the pattern layers PR1 and PR2 according to an embodiment may have a tapered shape. A width of the partition MB positioned between the transmissive layer TM2 and the pattern layers PR1 and PR2 may increase as it moves toward an upper surface of the transmissive layer TM2. Alternatively, the cross-sectional thickness W of the partition MB may become smaller toward the display unit DC.

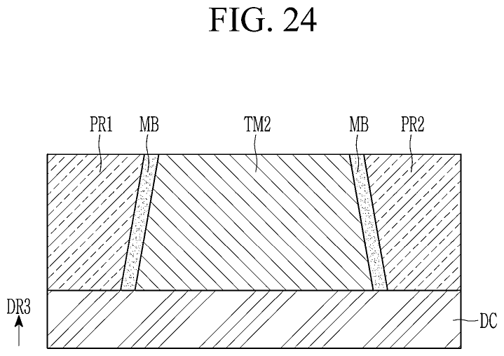

Referring to FIG. 24, the width of the transmissive layer TM2 according to an embodiment may become wider toward the display unit DC. Contrary to the transmissive layer TM2, the width of the pattern layers PR1 and PR2 may become smaller toward the display unit DC. The partition MB disposed between the pattern layers PR1 and PR2 and the transmissive layer TM2 may be provided with the same thickness.

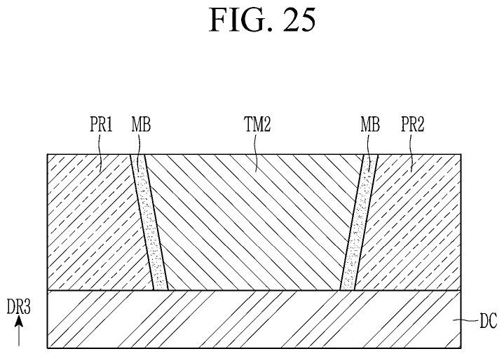

Referring to FIG. 25, the width of the transmissive layer TM2 according to an embodiment may become smaller as it moves toward the display unit DC. Contrary to the transmissive layer TM2, the width of the pattern layers PR1 and PR2 may increase toward the display unit DC. The partition MB disposed between the pattern layers PR1 and PR2 and the transmissive layer TM2 may be provided with the same thickness.

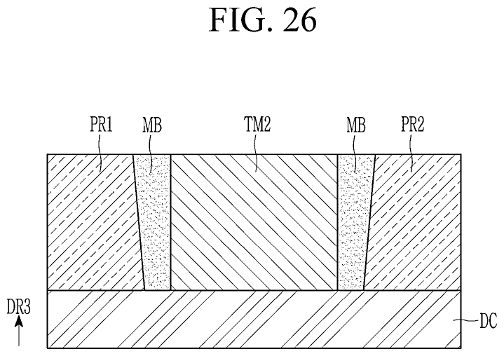

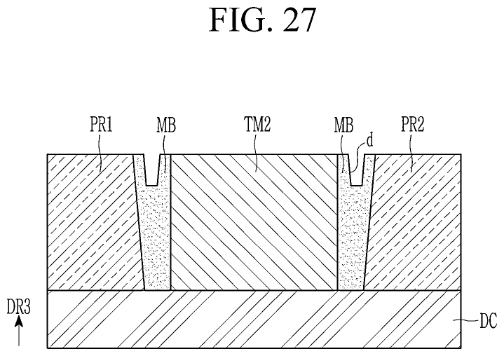

Referring to FIG. 26, the transmissive layer TM2 according to an embodiment may have substantially the same width in a cross-section. The width of the pattern layers PR1 and PR2 may increase toward the display unit DC in a cross-section. The width of the partition MB disposed between the pattern layers PR1 and PR2 and the transmissive layer TM2 may become smaller toward the display unit DC in a cross-section. Referring to FIG. 27, the partition MB according to an embodiment may include a recessed portion (d). The upper surface of the partition MB may have a recessed shape toward the display unit DC.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A display device, comprising:
a substrate;
a transistor disposed on the substrate;
a light emitting element electrically connected to the transistor;
an encapsulation layer disposed on the light emitting element;
a partition disposed on the encapsulation layer and defining a first opening, a second opening, and a third opening;
a first color conversion layer disposed within the first opening;
a second color conversion layer disposed within the second opening; and
a transmissive layer disposed within the third opening,
wherein the partition is made of metal, and
a distance from a center of a portion of the partition to the first color conversion layer is equal to a distance from the center of the portion of the partition to the transmissive layer.

2. The display device of claim 1, wherein
the partition is a single layer.

3. The display device of claim 1, wherein
the transmissive layer, the first color conversion layer, the transmissive layer, and the second color conversion layer are repeatedly disposed along a first direction.

4. The display device of claim 1, wherein
an upper surface of the transmissive layer is disposed at a higher level than an upper surface of the first color conversion layer.

5. The display device of claim 1, wherein
the partition has a thickness of a range of and including about 0.1 to 5 micrometers.

6. The display device of claim 1, comprising
a pattern layer spaced apart from the light emitting element.

7. The display device of claim 6, wherein
the pattern layer includes the same material as the transmissive layer.

8. The display device of claim 7, wherein
the pattern layer is disposed on the same layer as the first color conversion layer, the second color conversion layer, and the transmissive layer.

9. The display device of claim 6, wherein
the pattern layer is disposed between the first color conversion layer and the second color conversion layer along a first direction.

10. The display device of claim 1, wherein
a width of the first color conversion layer is greater than a width of the transmissive layer.

11. The display device of claim 1, further comprising
a light blocking layer disposed on the same layer as the partition.

12. The display device of claim 1, wherein
a thickness of the partition decreases toward the substrate.

13. The display device of claim 1, wherein
an upper surface of the partition includes a depression.

14. The display device of claim 12, wherein
the transmissive layer has a tapered shape.

15. A display device, comprising:
a substrate;
a transistor disposed on the substrate;
a light emitting element electrically connected to the transistor;
an encapsulation layer disposed on the light emitting element;
a partition disposed on the encapsulation layer and defining a first opening, a second opening, and a third opening;
a first color conversion layer disposed within the first opening;
a second color conversion layer disposed within the second opening; and
a transmissive layer disposed within the third opening,
wherein the partition is a single layer of metal.

16. The display device of claim 15, wherein
an upper surface of the transmissive layer is disposed at a higher level than an upper surface of the first color conversion layer.

17. The display device of claim 15, wherein
the partition has a thickness of a range of and including about 0.1 to 5 micrometers.

18. The display device of claim 15, wherein
the transmissive layer, the first color conversion layer, the transmissive layer, and the second color conversion layer are repeatedly disposed along a first direction.

19. The display device of claim 15, comprising
a pattern layer spaced apart from the light emitting element.

20. The display device of claim 19, wherein
the pattern layer is disposed between the first color conversion layer and the second color conversion layer along a first direction.
